(19) United States
(12) Patent Application Publication
(10) Pub. No.: US 2004/0011466 A1
(43) Pub. Date: Jan. 22, 2004

(54) Plasma processing apparatus

(75) Inventors: Naoki Matsumoto, Nirasaki-shi (JP); Chishio Koshimizu, Nirasaki-shi (JP); Toshiaki Hongoh, Nirasaki (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Tokyo (JP)

(21) Appl. No.: 10/618,602

(22) Filed: Jul. 15, 2003

(30) Foreign Application Priority Data
Jul. 16, 2002 (JP) 2002-207161

(51) Int. Cl. H01L 21/306

(52) U.S. Cl. 156/345.48

(57) ABSTRACT

A plasma processing apparatus for supplying radio-frequency power into a process chamber so as to generate plasma, to thereby treat an object to be processed with the plasma. In the plasma processing apparatus, the process chamber has a top plate which is disposed opposite to the object to be processed, through the medium of a region for generating the plasma, and a radio-frequency antenna is disposed in the inside and outside of the process chamber so that the radio-frequency antenna is wound around the top plate.

### BACKGROUND OF THE INVENTION

The present invention relates to a plasma processing apparatus which is suitably usable in a case where an object to be processed (such as base material (or substrate) for an electronic device) is plasma-treated for the purpose of manufacturing an electronic device, etc. More specifically, the present invention relates to a plasma processing apparatus which can generate high-density plasma with high efficiency.

In general, the plasma processing apparatus according to the present invention is widely applicable to the plasma processing of an object to be processed (e.g., materials for electronic devices such as semiconductors or semiconductor devices, and liquid crystal devices).

### RELATED BACKGROUND ART

In recent years, as the electronic devices such as semiconductor devices are caused to have a higher density and a finer structure or configuration, in the processes for manufacturing these electronic devices, the number of cases wherein a plasma processing apparatus is used for conducting various kinds of processing or treatments such as film formation, etching, and ashing has been increased. When such a plasma processing is used, it is generally advantageous that high-precision process control is facilitated in the process for manufacturing the electronic devices.

For example, as compared with the production of a semiconductor device (in this case, usually, the area to be processed is relatively small), the material to be processed (for example, a wafer) in the production of a liquid crystal device (LCD) has a larger diameter in many cases. Accordingly, when a plasma processing apparatus is used for the production of liquid crystal devices, the plasma to be used for the plasma processing is particularly required to be uniform and to have a high density over a large area.

Heretofore, CCP (capacitively coupled plasma)-type or parallel-plate plasma-type processing apparatuses and ICP (inductively coupled plasma) processing apparatuses have been used as the plasma processing apparatus.

Among these, in the case of the above CCP-type processing apparatus, there is generally used a process chamber having a pair of parallel plates, which has an Si top or ceiling plate having a shower head structure, for providing a more uniform flow of a process gas, provided as the upper electrode constituting one of the pair of the above parallel plates, and a susceptor which can apply a bias to the lower electrode as the other of the above pair of the parallel plates. In the plasma processing in this case, a substrate to be processed (an object to be processed) is placed on the susceptor, and plasma is caused to be generated between the above-mentioned upper electrode and lower electrode, so that the substrate is processed in a predetermined manner on the basis of the thus generated plasma.

However, in this CCP-type processing apparatus, as compared with other plasma sources, the resultant plasma density is relatively low and a sufficient ion flux is less liable to be obtained, so that the rate of the processing on the object to be processed (such as wafer) tends to be lower. In addition, even when the frequency of a power supply for providing electric power to the parallel plates is increased, a distribution in electric potential appears in the electrode plane constituting the parallel plates and, accordingly, the resultant uniformity in the plasma and/or process is liable to be decreased. In addition, the consumption of the Si electrode is considerably heavy in the CCP-type processing apparatus and, accordingly, the resultant cost tends to become higher in view of the COC (Cost of Consumables) in this case.

On the other hand, in the above-mentioned ICP processing apparatus, in general, a turn coil to which a radio-frequency power is to be supplied is disposed on a dielectric top plate located in an upper portion of a processing chamber (i.e., on the outside of the chamber), plasma is generated immediately below the top plate, on the basis of the induction heating due to the coil, and the object to be processed is treated on the basis of the thus generated plasma.

In the conventional ICP processing apparatus, radio-frequency power is applied to the turn coil disposed outside of the processing chamber, to thereby generate plasma in the process chamber (that is, the supplied radio-frequency power generates plasma in the process chamber through the medium of the dielectric top plate). Accordingly, when the substrate (the object to be processed) has a larger diameter, a considerable mechanical strength must be imparted to the process chamber, in view of vacuum sealing, and the thickness of the dielectric top plate is inevitably increased, and accordingly the resultant cost becomes higher. In addition, when the thickness of the dielectric top plate is increased, the transmission efficiency of the electric power from the turn coil to the plasma is decreased and, accordingly, the voltage applied to the coil is inevitably set to a higher value. As a result, the tendency that the dielectric top plate per se is subjected to sputtering is strengthened, and the above-mentioned COC becomes worse. Further, any foreign substance or contaminant which has been generated by this sputtering can be accumulated on the substrate, and the process performance can be worsened. In addition, the turn coil per se is required to have a larger size and it becomes necessary to use a power supply of higher output to supply electric power to a coil having such a large size.

As described hereinabove, the prior art could not realize a plasma processing apparatus which can generate high-density plasma with a high efficiency, particularly when an object to be processed having a larger area is to be used for the purpose of producing a liquid crystal device, etc.

### SUMMARY OF THE INVENTION

An object of the present invention is to provide a plasma processing apparatus which has solved the above-mentioned problem encountered in the prior art.

Another object of the present invention is to provide a plasma processing apparatus which can generate high-density plasma with a high efficiency, even when an object to be processed having a larger area is to be treated.

As a result of earnest study, the present inventors have found that it is extremely effective in solving the above-mentioned object to cause the top plate of a process chamber to have a specific configuration and to supply radio-frequency power to the inside of a process chamber.

The plasma processing apparatus according to the present invention is based on the above discovery. More specifically, the present invention provides a plasma processing apparatus for supplying radio-frequency power into a process chamber so as to generate plasma, to thereby treat an object to be processed with the plasma;

wherein the process chamber has a top plate which is disposed opposite to the object to be processed, through the medium of a region for generating the plasma; and a radio-frequency antenna is disposed in the inside and outside of the process chamber so that the radio-frequency antenna is wound around the top plate.

The present invention also provides a plasma processing apparatus for supplying radio-frequency power into a process chamber so as to generate plasma, to thereby treat an object to be processed with the plasma;

wherein the process chamber has a top plate which is disposed opposite to the object to be processed through the medium of a region for generating the plasma; and the top plate comprises a metal-based or silicon-based material.

A further scope of applicability of the present invention will become apparent from the detailed description given hereinafter. However, it should be understood that the detailed description and specific examples, while indicating preferred embodiments of the invention, are given by way of illustration only, because various changes and modifications within the spirit and scope of the invention will become apparent to those skilled in the art from this detailed description.

### BRIEF DESCRIPTION OF THE DRAWINGS

FIG. 1A is a schematic perspective view showing an embodiment of the plasma processing apparatus according to the present invention.

FIG. 1B is a schematic sectional view showing the direction of a current and the direction of an electric field based on the antenna arrangement in the plasma processing apparatus as shown in FIG. 1A.

FIG. 2 is a schematic sectional view showing the direction of a current and the direction of an electric field based on another antenna arrangement.

FIG. 3 is a schematic perspective view showing an embodiment of the radio-frequency antenna supported by one of the chamber walls in a cantilever form.

FIG. 4 is a schematic perspective view showing an embodiment of the radio-frequency antenna supported by both of the chamber walls in a cantilever form.

FIG. 5 is a schematic perspective view showing an example of the plasma processing apparatus wherein the shape of the top plate has been changed.

FIG. 6 is a schematic perspective view showing another example of the plasma processing apparatus wherein the shape of the top plate has been changed.

FIG. 7 is a schematic perspective view showing a further example of the plasma processing apparatus wherein the shape of the top plate has been changed.

FIG. 8 is a schematic perspective view showing a further example of the plasma processing apparatus wherein the shape of the top plate has been changed.

FIG. 9 is a schematic sectional view showing an embodiment of the plasma processing apparatus according to the present invention wherein a reflection-free terminator is provided on the termination of a radio-frequency transmission line.

FIG. 10 is a schematic sectional view showing an embodiment of the plasma processing apparatus according to the present invention wherein a capacity-variable tuner is provided between a radio-frequency transmission line and an antenna.

FIG. 11 is a schematic sectional view showing another embodiment of the plasma processing apparatus according to the present invention wherein a capacity-variable tuner is provided between a radio-frequency transmission line and an antenna.

FIG. 12 is a schematic sectional view showing a further embodiment of the plasma processing apparatus according to the present invention wherein a capacity-variable tuner is provided between a radio-frequency transmission line and an antenna.

FIG. 13 is a schematic sectional view showing a further embodiment of the plasma processing apparatus according to the present invention wherein a capacity-variable tuner is provided between a radio-frequency transmission line and an antenna.

FIG. 14 is a partial schematic sectional view showing an embodiment of the plasma processing apparatus according to the present invention wherein a photoelectric sensor is provided in the process chamber.

FIG. 15 is partial schematic sectional view showing an embodiment of the plasma processing apparatus according to the present invention wherein an opening is provided on a grounded line in the process chamber.

FIG. 16 is partial schematic sectional view showing another embodiment of the plasma processing apparatus according to the present invention wherein an opening is provided on a grounded line in the process chamber.

FIG. 17 is a schematic sectional view showing an embodiment of the plasma processing apparatus according to the present invention.

FIG. 18A is a schematic perspective view showing an embodiment of the plasma processing apparatus according to the present invention as shown in FIG. 17.

FIG. 18B is a schematic sectional view showing the direction of a current and the direction of an electric field based on the antenna arrangement as shown in FIG. 18A.

### DETAILED DESCRIPTION OF PREFERRED EMBODIMENTS

Hereinbelow, the present invention will be described in detail with reference to the accompanying drawings, as desired. In the following description, “%” and “part(s)” representing a quantitative proportion or ratio are those based on mass, unless otherwise noted specifically.

(One Embodiment of Plasma Processing Apparatus)

The plasma processing apparatus according to the present invention is a plasma processing apparatus wherein a radio-frequency (electric) power is supplied into a process chamber thereof so as to generate plasma in the process chamber, to thereby treat an object to be processed. In an embodiment of the present invention, the top plate constituting the process chamber comprises a metal-based or silicon-based material. When the top plate is constituted by a metal-based material, at least the side of the top plate facing the inside of the process chamber is covered with an insulating substance.

When the top plate is constituted by a metal-based or silicon-based material in this manner, it becomes easy to cause the top plate to have a shower head structure. Accordingly, in this case, the partial pressure and/or composition, etc., of a reactant gas in the plasma treatment is made uniform and, accordingly, it is possible to further enhance the uniformity in the plasma treatment.

Further, when the top plate is constituted by the metal-based material, the ignition of the plasma is facilitated on the basis of the capacitive coupling with the lower electrode, and the control of the drawing or introduction of the plasma is also facilitated.

On the other hand, when the top plate is constituted by a silicon-based material, the prevention of particulate material production is further facilitated.

(Antenna Arrangement)

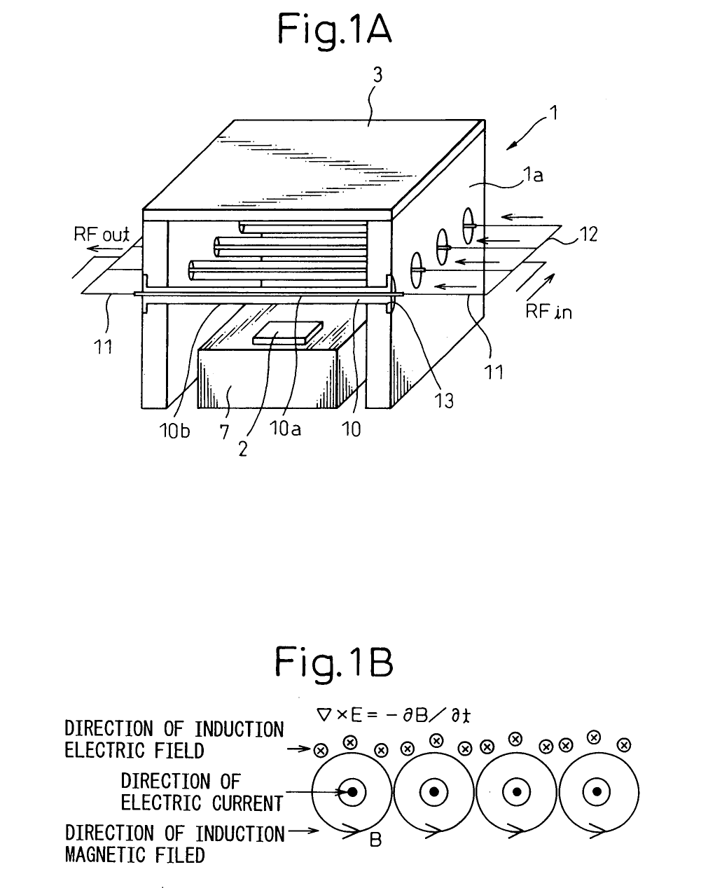

FIG. 1A is a schematic perspective view showing an embodiment of the constitution (or structure) of the plasma processing apparatus according to the present invention.

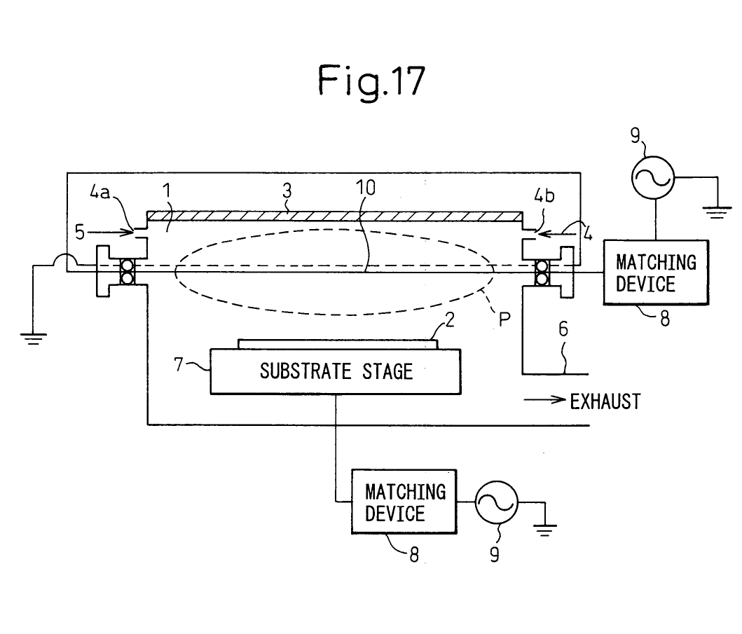

Referring to FIG. 1A, the process chamber 1, as a vacuum container in such an embodiment, is formed into, e.g., a rectangular parallelepiped shape. The process chamber 1 has a top plate 3 which is disposed opposite to an object 2 to be processed (such as wafer) via (or through the medium of) a region P (as shown in FIG. 17) in which the above-mentioned plasma is to be generated. In this embodiment, the top plate 3 is constituted by a metal-based or silicon-based material.

Further, a gas introduction pipe (not shown) for supplying, into the inside of the process chamber 1, a gas such as a process gas (e.g., a reactive gas for etching, a source gas for CVD (chemical vapor deposition)), and inert gas (e.g., Ar) is connected to the upper part of the process chamber 1. On the other hand, an exhaust pipe (not shown) for evacuating the process chamber 1 is connected to the process chamber 1. The process chamber 1 may be formed not only into a rectangular parallelepiped shape, but also into a cylindrical or tubular shape.

A exhaust pump is connected to the above-mentioned exhaust pipe via a pressure control valve (not shown), and process chamber is maintained at a desired pressure by the action of the exhaust pump.

In the process chamber 1, a substrate stage 7 is provided, and the above-mentioned object to be processed (such as a wafer) 2 which is to be subjected to a treatment such as etching and CVD is placed on the substrate stage 7. A power supply (not shown) is connected to the substrate stage 7 via a matching device (not shown) so that a bias having a predetermined voltage may be applied to the substrate stage 7.

In the process chamber 1, a radio-frequency antenna 10 in a linear form is disposed so that the antenna 10 is placed across the process chamber 1. In the present invention, it is sufficient that the antenna 10 is linear as a whole (in other words, a curved portion may be present in the linear antenna 10). One or more antennas 10 may be disposed in the process chamber 1. It is preferred that a plurality of the antennas 10 are disposed in the process chamber 1.

With respect to the antenna 10, as shown in a schematic sectional view of FIG. 1A, radio-frequency power is distributed by a distributor 11 so that the radio-frequency power can be supplied into the process chamber 1 from the plural antennas 10. In this embodiment, each of the antennas 10 comprises an electroconductive rod 10a, and an insulating tube 10b disposed around the electroconductive rod 10a.

In the embodiment shown in FIG. 1A, the electric current flows in each of the antennas 10 in one direction (in a portion thereof which is disposed inside the process chamber 1) so that the directions of the respective electric currents in the plural antennas 10 are the same. Based on such a direction of the current, as shown in FIG. 1B, the induction electric fields due to the electric currents in the respective plural antennas 10 disposed inside the process chamber 1 are strengthened by each other, on the basis of the interactions therebetween.

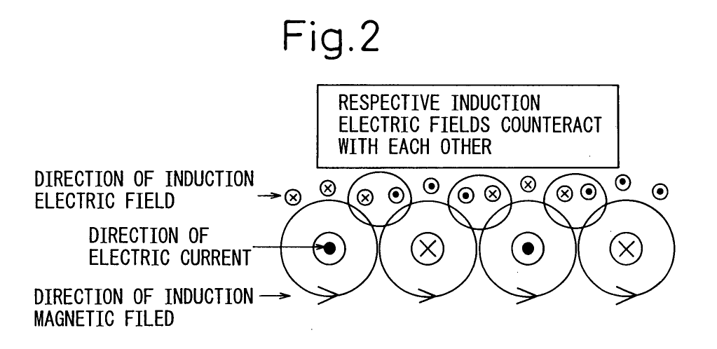

On the other hand, when the electric current flows in each of the antennas 10 so that the directions of the respective electric currents in the plural antennas 10 are reverse to each other as shown in a schematic sectional view of FIG. 2, the induction electric fields due to the electric currents in the respective plural antennas 10 counteract each other.

In the embodiment of FIG. 1A, the radio-frequency power is propagated in the transmission line comprising the electroconductive rod 10a and the insulating tube 10b. When the electric field strength in the insulating tube 10b reaches a threshold level on the outer wall surface of the insulating tube 10b, plasma is ignited in the plasma generating region P (as shown in FIG. 17) in the process chamber 1.

After the plasma ignition, it is preferred to conduct matching by using a tuner (for example, stub tuner; not shown) as the variable capacity on the power supply side, so as to control the reflection electric power, whereby the reflection electric power is not returned to the power supply.

(One Embodiment of Arrangement of Plural Antennas)

An embodiment of the arrangement of plural antennas will be described in more detail while referring to a schematic perspective view of FIG. 1A. In this embodiment, as described above, radio-frequency power propagating in coaxial lines 12 from a radio-frequency power source (not shown) is distributed into plural directions by a distributor 11. Each of the thus distributed radio-frequency power is propagated along the electroconductive rod (antenna) 10a which is supported by the chamber wall 1a via an insulating material 13 disposed between the rod 10a and the chamber wall 1a, to the inside of the process chamber 1. In general, the electroconductive rod 10a is protected by the insulating tube (quartz tube, for example) 10b, so that the electroconductive rod 10a does not contact the plasma directly. In addition, the process chamber 1 side is vacuum-sealed by the insulating tube 10b and an O-ring (not shown). Accordingly, the pressure in the inside of the insulating tube 10b may be atmospheric pressure. In the embodiment of FIG. 1A, the electroconductive rod 10a is arranged so that it penetrates the right and left chamber walls 1a. The length of the electroconductive rod 10a may preferably be within the range corresponding to {n/2 times (n: integer) the wavelength λ₀ of the radio-frequency±1/4λ₀} (in other words, (n/2−1/4)λ₀≦(length of electroconductive rod 10a)≦(n/2+1/4)λ₀).

The length, shape, form of the arrangement, etc., of the electroconductive rod 10a are not particularly limited. The thickness or diameter of the electroconductive rod 10a may be changed as desired, so that the thickness or diameter is changed along with the radio-frequency propagation direction.

As described hereinabove, it is possible to provide a tuner or a capacity-variable mechanism (not shown) between the individual electroconductive rods 10a and the distributor 11. When the capacity is regulated in this manner so as to change the degree of coupling, the efficiency of the electric power transmission from the distributor 11 may be regulated, so that the plasma distribution can be controlled depending. on the process gas, pressure region, etc.

Unlike in a case where plasma is generated by supplying microwave power, the layout of the electroconductive rod 10a can freely be determined so that the electroconductive rod 10a can be disposed at an arbitrary position. Accordingly, the plasma generation location can be controlled, by changing the arrangement of the electroconductive rods 10a so that the density (degree of density and sparseness) of the electroconductive rods 10a is changed with respect to the central portion and periphery of the process chamber 1, and/or the density of the electroconductive rods 10a is changed with respect to the height direction of the process chamber 1.

The degree of coupling with plasma can be changed by changing the thickness or diameter of the electroconductive rod 10a. In addition, the electroconductive rod 10a can be cooled by circulating an insulating gas or insulating liquid in the clearance between the electroconductive rod 10a and the insulating tube 10b.

As described hereinabove, when the plasma source having the above-mentioned constitution or structure is disposed in the process chamber 1 having a metal-based or silicon-based top plate, a uniform plasma corresponding to a large-diameter chamber can easily be obtained.

(Other Embodiments of Antenna Arrangement)

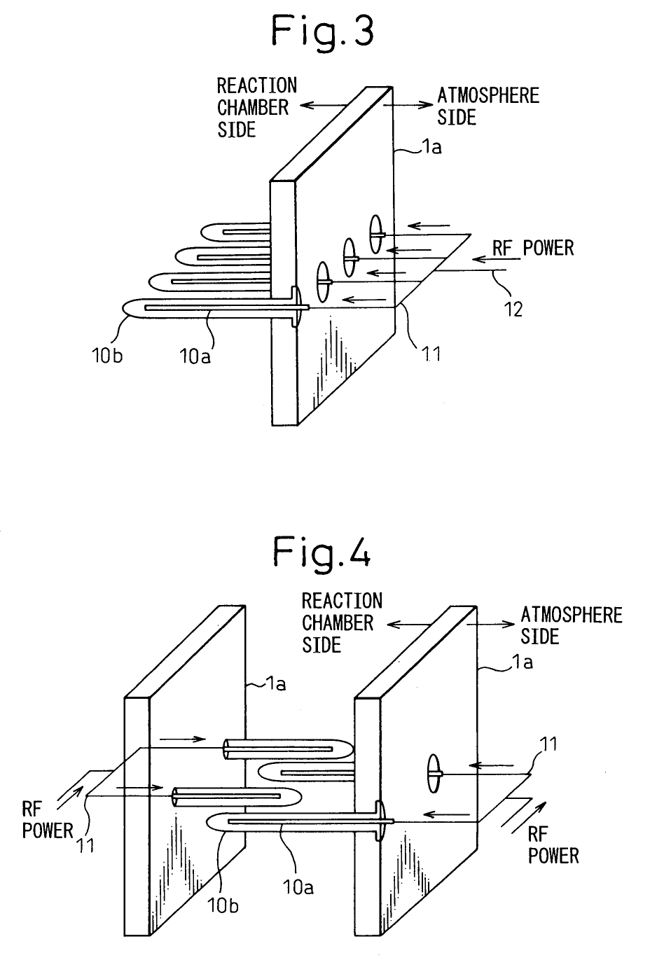

The schematic perspective view of FIG. 3 shows a second embodiment of the antenna arrangement. The constitution in the embodiment of this FIG. 3 is the same as that of FIG. 2 except that the antenna (electroconductive rod) is supported by the chamber wall la as a cantilever type.

The schematic perspective view of FIG. 4 shows a third embodiment of the antenna arrangement. The constitution in the embodiment of this FIG. 4 is the same as that of FIG. 3 except that the antennas (electroconductive rods) are respectively supported by the right and left chamber walls la as a cantilever type.

(Shapes of Top Plate)

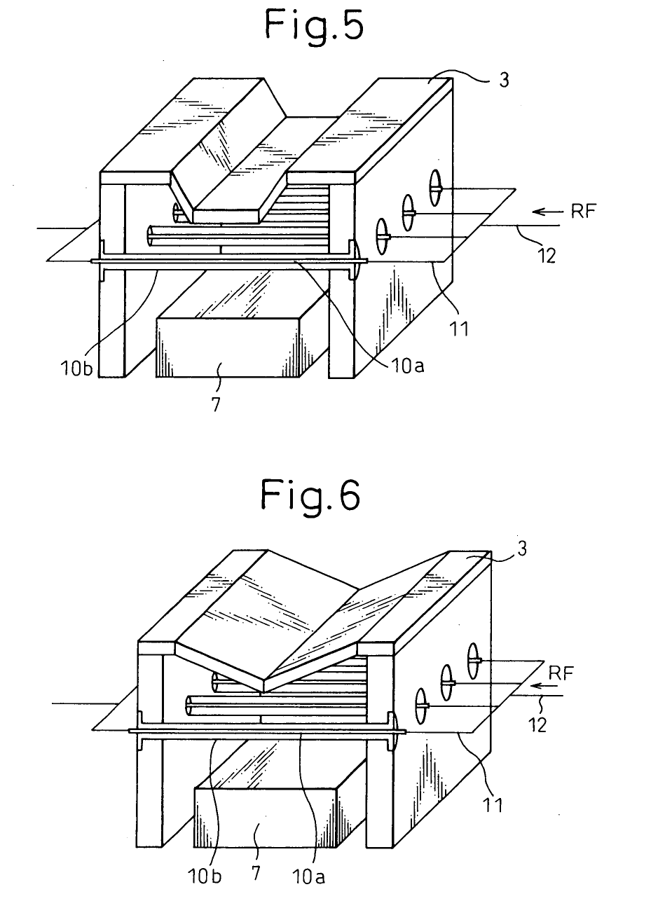

The schematic perspective views of FIGS. 5-8 show other embodiments of the top plate shape. In these figures, the shape of top plate 3 has been changed so as to impart a non-uniform distribution to the distance between the antenna 10a and the top plate 3 (with respect to the longitudinal direction of the antenna 10a). It is also possible to constitute the shape of the top plate 3 in these figures so that a non-uniform distribution is imparted between the respective elements constituting the array of the antennas 10a (in other words, a non-uniform distribution is imparted along the direction which is perpendicular to the longitudinal direction of the antenna 10a).

Among the above-mentioned embodiments, as shown in FIG. 5 or FIG. 6, the central portion of the top plate 3 is protruded toward the inside of the chamber so that the distance between the top plate 3 and the antenna 10a in the central portion is smaller than that in the peripheral portion, whereby the capacitive coupling between the antenna 10a and the top plate 3 is enhanced, the electric field strength at the time of the ignition is enhanced, and the plasma generating region is relatively limited. For example, in a case where an RIE (reactive ion etching) processing is intended, the bias distribution can be made uniform in a region of the top plate 3 facing the substrate surface.

In addition, as shown in a schematic perspective view of FIG. 6, the antennas are arranged so as to provide a distribution such that the central portion of the antenna is made nearer to the top plate 3, whereby the capacitive coupling between the antenna 10a and the top plate 3 is enhanced, the electric field strength at the time of the ignition is enhanced, and the plasma generating region is relatively limited, in the same manner as in FIG. 5.

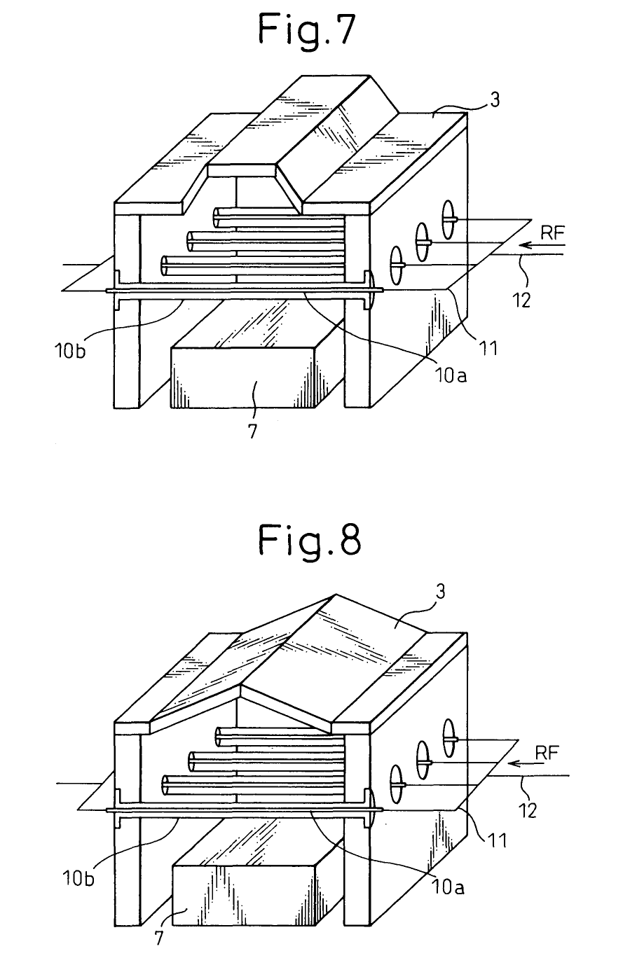

On the other hand, as shown in a schematic perspective view of FIG. 7, the central portion of the top plate 3 is raised so that the distance between the top plate 3 and the antenna 10a in the central portion is made larger than that in the peripheral portion thereof, whereby the capacitive coupling between the antenna and the plasma at the peripheral portion is increased, and therefore plasma is generated in the peripheral portion. For example, in a case where radical treatment is intended, plasma can be generated in the peripheral portion, and the processing on the substrate surface can be made uniform due to diffusion.

In addition, as shown in a schematic perspective view of FIG. 8, the antennas 10a are arranged so as to provide a distribution such that the distance between the central portion of the antennas 10a and the top plate 3 is larger than that in the peripheral portion thereof, whereby the capacitive coupling between the antennas 10a and the plasma at the peripheral portion is increased, and therefore plasma can be generated in the peripheral portion.

(Provision of Reflection-Free Terminator)

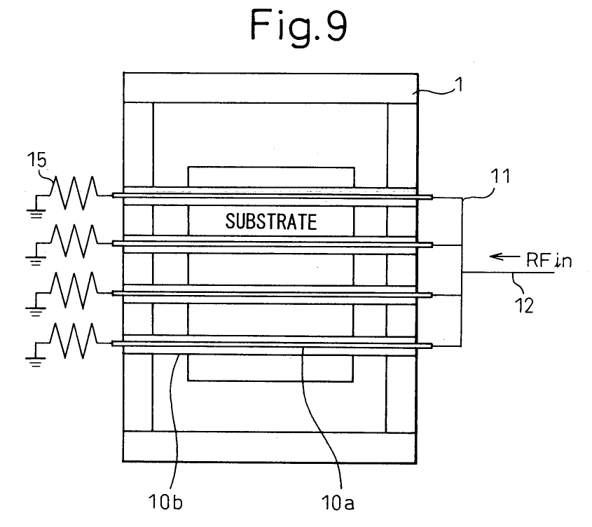

In the plasma processing apparatus according to the present invention, it is also possible to dispose a reflection-free terminator 15 at the terminal of a transmission line for radio-frequency power, as desired. The schematic sectional view of FIG. 9 shows an embodiment of such a constitution.

In FIG. 9, a plurality of antennas 10a are arranged in the process chamber 1 so that they penetrate the chamber walls la disposed opposite to each other, and further reflection-free terminators 15 are disposed at the terminal of the antennas 10a.

(Embodiment wherein Antenna is Movable)

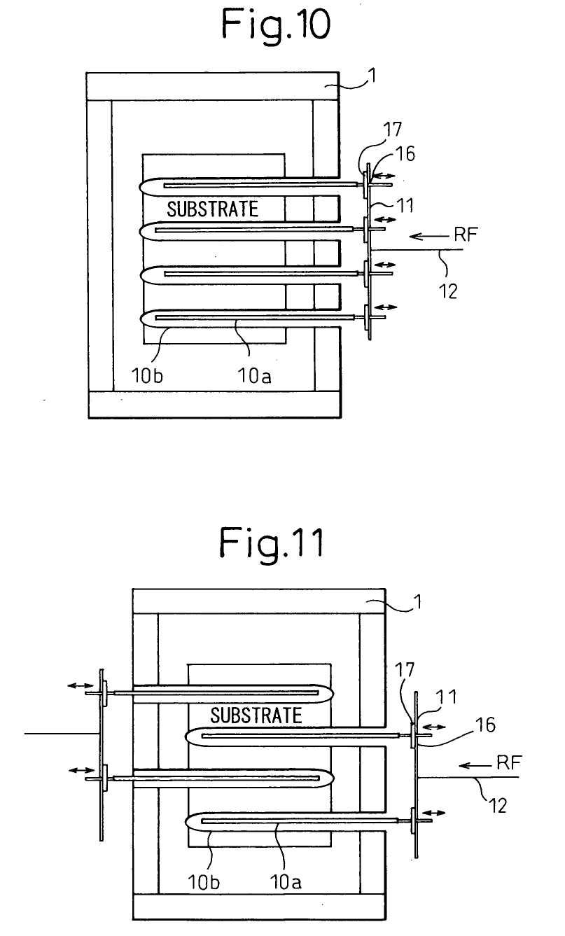

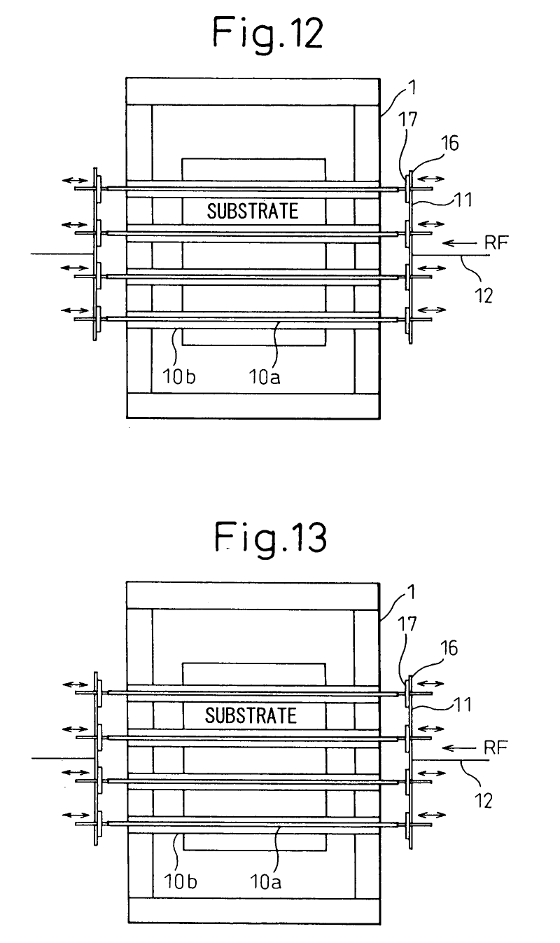

The location or position of each antenna 10a can also be movable or changeable, depending on a certain condition such as process gas, pressure, and electric power. The schematic plan views of FIG. 10 to FIG. 13 show examples of such an embodiment. In these embodiments, for example, a tuner 16 of which position is controllable by using an external action is provided while being supported by an insulating insulator 17, the tuner 16 is driven as desired so as to change the position of the antenna 10a, whereby plasma distribution in the process chamber 1 can be changed.

In this case, it is possible that, for example, an electroconductive jig (not shown) supported by an insulating insulator 17 is provided between the antenna 10a (electroconductive rod) and the insulating insulator 17, so that the jig is always caused to contact the antenna 10a so as to provide a low resistance therebetween, while being slidably supported by the antenna 10a in a multi-contact manner, etc.

(Provision of Sensor)

Depending on a certain condition such as process gas, pressure, and electric power, the distribution ratio of the electric power to be supplied to each the antenna 10a can be changed, and the resultant plasma may become ununiform. In such a case, it is possible that the distribution of the plasma density is externally monitored during plasma generation, as desired, by using a photoelectric sensor, etc., and the results of the sensor monitoring are fed back to a variable tuner. In this case, it is possible that the degree of coupling of the respective antennas 10a and radio-frequency transmission line 12 is regulated on the basis of the above monitoring, whereby the plasma distribution can be made uniform with respect to the entire region.

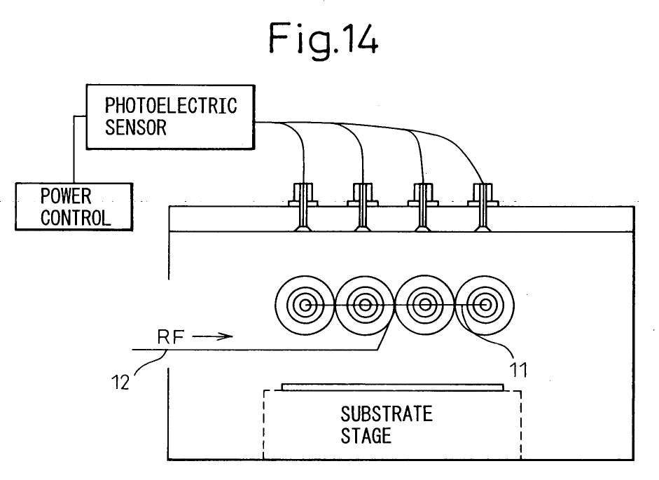

FIG. 14 shows an example of such an embodiment. In this case, for example, the coupling between the radio-frequency transmission line 12 and the antenna 10a can be strengthened by regulating the capacity of the tuner so as to supply electric power to the antenna 10a. On the contrary, the coupling between the radio-frequency transmission line 12 and the antenna 10a can be weakened by regulating the capacity of the tuner. It is also possible that a library is preliminarily prepared with respect to each of process conditions so that the condition (capacity of the tuner) can provide uniform plasma, and the capacity of the tuner is regulated in such a manner after the plasma ignition.

In this case, when the number of the antennas 10a is relatively large, the sensors and the antennas 10a are subjected to grouping, and the capacity of the tuners may be regulated corresponding to each of the resultant groups. Further, it is also possible that the outputs of the photoelectric sensor are converted into the distribution or uniformity of plasma, or distribution or rate of the process (such as etching and CVD) by using a database or a theoretical formula, and the tuner is controlled so as to provide the desired results.

(Provision of Partial Opening on Ground Line)

In the present invention, as desired, it is possible that an opening is provided with respect to at least a part of the ground line 20 in the process chamber 1, and the radio-frequency electric field is externally emitted from the opening portion 20a so as to generate plasma in the process chamber 1, whereby the plasma distribution is regulated by changing the position of the opening portion 20a. On the basis of such regulation of the plasma distribution, a desired plasma distribution can be obtained more easily.

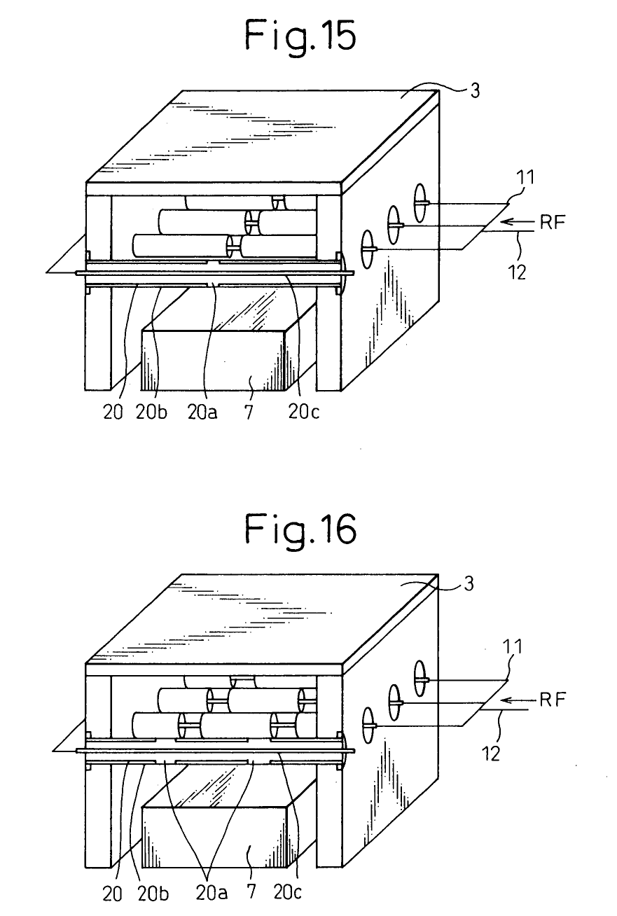

The schematic perspective views of FIG. 15 and FIG. 16 show an example of such an embodiment. In these figures, the ground line 20 is usually constituted by a coaxial line. Referring to FIG. 15, the ground line 20 of the transmission line in the process chamber 1 is constituted by a coaxial line which comprises a core wire 20c, and the inner wall of an electroconductive tube, or an insulating tube 20b of which outside is covered with plating. When the covering or coating of the ground line 20 is removed with respect to a part of the coaxial line, the resultant opening portion 20a provides a high impedance in view of the impedance, so that the voltage is enhanced. A strong electric field can be generated by the resultant high potential so as to ignite plasma. In addition, the radio-frequency energy is supplied from the opening portion 20a, the plasma begins to spread outward from this point depending on an increase in the electric power. In other words, it is possible to determine the position of this opening portion so that it can provide a desired plasma distribution.

The constitution of FIG. 16 is the same as that of FIG. 15 except the above-mentioned two opening portions are provided with respect to the transmission line in the chamber.

(Other Embodiments of Plasma Processing Apparatus)

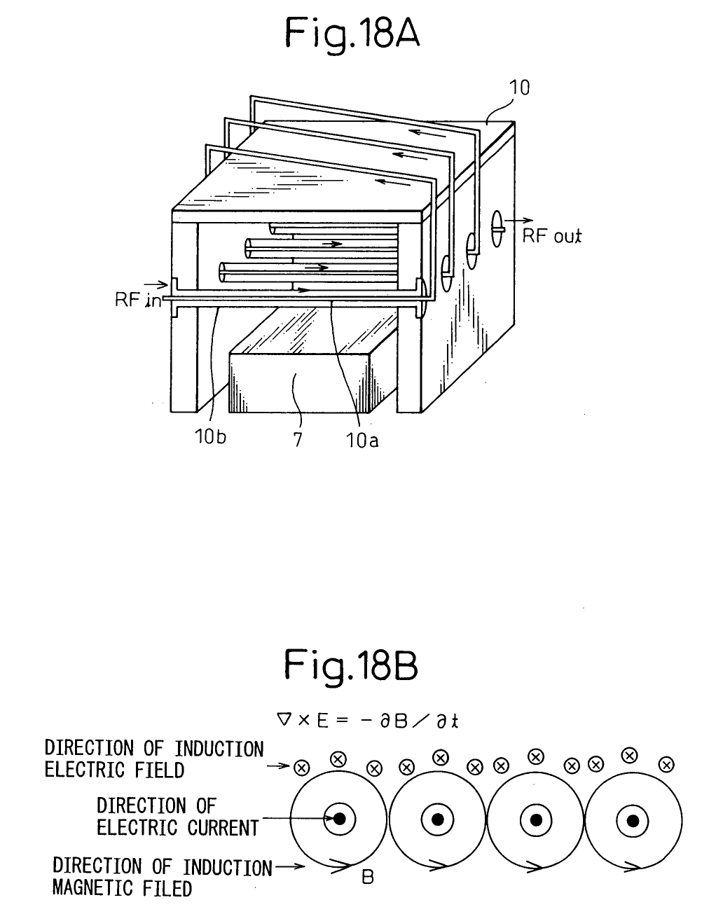

The schematic perspective view of FIG. 18 shows another embodiment of the plasma processing apparatus according to the present invention. In this embodiment, a radio-frequency antenna 10a is disposed inside of the process chamber 1 and the outside of the process chamber 1 so that the radio-frequency antenna 10a is wound around the process chamber top plate 3.

(Antenna Arrangement)

FIG. 17 is a schematic sectional view showing an embodiment of the constitution of a plasma processing apparatus according to the present invention, and FIG. 18A is a schematic perspective view showing the detailed arrangement of the antenna 10a shown in FIG. 17.

Referring to FIG. 17 and FIG. 18A, in such an embodiment, an antenna 10a is disposed inside the process chamber 1 and outside the process chamber 1 so that the antenna 10a is wound around the top plate 3 disposed in the upper portion of the process chamber 1. That is, as shown in FIG. 18A, the electric current flows in the antennas 10a in one direction so that the directions of the respective electric currents in the plural antennas 10a are the same. Based on such a direction of the current, as shown in FIG. 18B, the induction electric fields based on the electric currents in the respective plural antennas 10a disposed inside the process chamber 1 are strengthened by each other.

Accordingly, in the embodiments shown in FIGS. 17 and 18A, high density plasma can easily be generated with a high efficiency, in the same manner as in the embodiment shown in the FIG. 1A as described hereinabove.

As described hereinabove, the present invention can provide a plasma processing apparatus which can generate high-density plasma with a high efficiency, even in the case of the treatment of an object to be processed having a large area.

From the invention thus described, it will be obvious that the invention may be varied in many ways. Such variations are not to be regarded as a departure from the spirit and scope of the invention, and all such modifications, as would be obvious to one skilled in the art, are intended to be included within the scope of the following claims.

The present application is based on Japanese priority application No. 2002-207161 filed on Jul. 16, 2002, the entire contents of which are hereby incorporated by reference.

What is claimed is:

1. A plasma processing apparatus for supplying radio-frequency power into a process chamber so as to generate plasma, to thereby treat an object to be processed with the plasma;
wherein the process chamber has a top plate which is disposed opposite to the object to be processed, through the medium of a region for generating the plasma; and a radio-frequency antenna is disposed in the inside and outside of the process chamber so that the radio-frequency antenna is wound around the top plate.

2. A plasma processing apparatus according to claim 1, wherein at least one metal-based radio-frequency antenna is disposed, in the process chamber, so as to provide a linear and/or curved line.

3. A plasma processing apparatus according to claim 1, wherein the radio-frequency antenna disposed in the process chamber is covered with an insulating material so that the radio-frequency antenna does not directly contact the plasma.

4. A plasma processing apparatus according to claim 1, wherein the length of the radio-frequency antenna disposed in the process chamber is not smaller than (n/2−1/4)λ₀ (wherein λ₀ is the wavelength of the radio-frequency power, and n is an integer) and not larger than (n/2+1/4)λ₀.

5. A plasma processing apparatus according to claim 1, wherein the thickness or diameter of the radio-frequency antenna disposed in the process chamber is changed along with the propagation direction of the radio-frequency power

6. A plasma processing apparatus according to claim 1, wherein the radio-frequency antenna is disposed in the process chamber, so that the density of the radio-frequency antenna arrangement is changed with respect to the central portion and peripheral portion of the process chamber, and/or with respect to the height direction of the process chamber.

7. A plasma processing apparatus according to claim 3, wherein an insulating fluid is circulated between the radio-frequency antenna disposed in the process chamber, and the insulating material.

8. A plasma processing apparatus according to claim 1, wherein the distance between the top plate and the radio-frequency antenna disposed in the process chamber is variable.

9. A plasma processing apparatus according to claim 1, wherein a measuring device is disposed in at least one position of the top plate so as to monitor the state of the generated plasma.

10. A plasma processing apparatus according to claim 1, wherein the top plate has a plurality of apertures for passing a gas to be supplied to the process chamber.

11. A plasma processing apparatus according to claim 1, wherein a susceptor for supporting the object to be processed is disposed in the process chamber, and a bias is applied to the susceptor.

12. A plasma processing apparatus according to claim 1, wherein at least a portion of the ground line in the process chamber has an opening, and the plasma is generated due to the radiation of a microwave electric field from the opening toward the outside of the ground line.

13. A plasma processing apparatus for supplying radio-frequency power into a process chamber so as to generate plasma, to thereby treat an object to be processed with the plasma;
wherein the process chamber has a top plate which is disposed opposite to the object to be processed through the medium of a region for generating the plasma; and the top plate comprises a metal-based or silicon-based material.

14. A plasma processing apparatus according to claim 13, wherein at least one metal-based radio-frequency antenna is disposed, in the process chamber, so as to provide a linear and/or curved line.

15. A plasma processing apparatus according to claim 14, wherein the radio-frequency antenna disposed in the process chamber is covered with an insulating material so that the radio-frequency antenna does not directly contact the plasma.

16. A plasma processing apparatus according to claim 14, wherein the length of the radio-frequency antenna disposed in the process chamber is not smaller than (n/2−1/4)λ₀ (wherein λ₀ is the wavelength of the radio-frequency power, and n is an integer) and not larger than (n/2+1/4)λ₀.

17. A plasma processing apparatus according to claim 14, wherein the thickness or diameter of the radio-frequency antenna disposed in the process chamber is changed along with the propagation direction of the radio-frequency power

18. A plasma processing apparatus according to claim 14, wherein the radio-frequency antenna is disposed, in the process chamber, so that the density of the radio-frequency antenna arrangement is changed with respect to the central portion and peripheral portion of the process chamber, and/or with respect to the height direction of the process chamber.

19. A plasma processing apparatus according to claim 15, wherein an insulating fluid is circulated between the radio-frequency antenna disposed in the process chamber, and the insulating material.

20. A plasma processing apparatus according to claim 14, wherein the distance between the top plate and the radio-frequency antenna disposed in the process chamber is variable.

21. A plasma processing apparatus according to claim 14, wherein a measuring device is disposed in at least one position of the top plate so as to monitor the state of the generated plasma.

22. A plasma processing apparatus according to claim 14, wherein the top plate has a plurality of apertures for passing a gas to be supplied to the process chamber.

23. A plasma processing apparatus according to claim 14, wherein a susceptor for supporting the object to be processed is disposed in the process chamber, and a bias is applicable to the susceptor.

24. A plasma processing apparatus according to claim 14, wherein at least a portion of the ground line in the process chamber has an opening, and the plasma is generated due to the radiation of microwave electric field from the opening toward the outside of the ground line.
